(19) United States
(12) Patent Application Publication
(10) Pub. No.: US 2011/0151639 A1
(43) Pub. Date: Jun. 23, 2011

(54) SEMICONDUCTOR DEVICE, METHOD OF FABRICATING THE SAME, SEMICONDUCTOR MODULE, ELECTRONIC CIRCUIT BOARD, AND ELECTRONIC SYSTEM INCLUDING THE DEVICE

(76) Inventors: Jae-Soon Lim, Seoul (KR); Youn-Soo Kim, Yongin-si (KR); Jae-Hyoung Choi, Hwaseong-si (KR); Sang-Yeol Kang, Seoul (KR); Suk-Jin Chung, Hwaseong-si (KR)

(21) Appl. No.: 12/855,191

(22) Filed: Aug. 12, 2010

(30) Foreign Application Priority Data
Dec. 22, 2009 (KR) 10-2009-0129209

(51) Int. Cl. H01L 21/02

(52) U.S. Cl. 438/381; 257/E21.011

(57) ABSTRACT

Provided are a semiconductor device, a method of fabricating the same, and a semiconductor module, an electronic circuit board, and an electronic system including the device. The semiconductor device includes a lower electrode, a rutile state lower vanadium dioxide layer on the lower electrode, a rutile state titanium oxide on the lower vanadium dioxide layer, and an upper electrode on the titanium oxide layer.

### CROSS-REFERENCE TO RELATED APPLICATION

This application claims the benefit of Korean Patent Application No. 2009-0129209, filed Dec. 22, 2009, the contents of which are hereby incorporated herein by reference in their entirety.

### BACKGROUND

1. Field

Example embodiments relate to a semiconductor device including a capacitor, a method of fabricating the same, a semiconductor module, an electronic circuit board, and an electronic system including the device.

2. Description of Related Art

With an increase in the integration density of semiconductors, a semiconductor device having a capacitor with a higher dielectric constant has been in demand.

### SUMMARY

Example embodiments provide a semiconductor device including a capacitor having a rutile state vanadium dioxide layer and a rutile state titanium oxide layer.

Also, example embodiments provide a semiconductor module including a semiconductor device having a capacitor with a rutile state vanadium dioxide layer and a rutile state titanium oxide layer.

Furthermore, example embodiments provide an electronic circuit board including a semiconductor device having a capacitor with a ruffle state vanadium dioxide layer and a rutile state titanium oxide layer.

In addition, example embodiments provide an electronic system including a semiconductor device having a capacitor with a rutile state vanadium dioxide layer and a rutile state titanium oxide layer.

Moreover, example embodiments provide a method of fabricating a semiconductor device including a capacitor having a rutile state vanadium dioxide layer and a rutile state titanium oxide layer.

Aspects of the inventive concept should not be limited by the above description, and other unmentioned aspects will be clearly understood by one of ordinary skill in the art from example embodiments described herein.

According to example embodiments, a semiconductor device may include a lower electrode, a rutile state lower vanadium dioxide layer on the lower electrode, a rutile state titanium oxide layer on the lower vanadium dioxide layer, and an upper electrode on the titanium oxide layer.

According to other example embodiments, a semiconductor device may include a lower electrode, a rutile state titanium oxide layer on the lower electrode, a rutile state upper vanadium dioxide layer on the titanium oxide layer, and an upper electrode on the upper vanadium dioxide layer.

According to other example embodiments, a method of fabricating a semiconductor device may include forming a lower electrode, forming a rutile state lower vanadium dioxide layer on the lower electrode, forming a rutile state titanium oxide layer on the lower vanadium dioxide layer, and forming an upper electrode on the titanium oxide layer.

According to other example embodiments, a method of fabricating a semiconductor device may include forming a lower electrode, forming a titanium oxide layer including an amorphous portion on the lower electrode, forming a rutile state upper vanadium dioxide layer on the titanium oxide layer, and forming an upper electrode on the upper vanadium dioxide layer.

According to other example embodiments, a semiconductor module may include a module substrate, a plurality of semiconductor devices on the module substrate, and contact terminals in a row on an edge of the module substrate and electrically connected to the semiconductor devices. At least one of the semiconductor devices may include a capacitor structure, which includes a lower electrode, a rutile state lower vanadium dioxide layer on the lower electrode, a rutile state titanium oxide layer on the lower vanadium dioxide layer, and an upper electrode on the titanium oxide layer.

According to other example embodiments, an electronic circuit board may include a circuit board, a microprocessor (MP) on the circuit board, a main storage circuit and a supplementary storage circuit configured to communicate with the MP, an input signal processing circuit configured to transmit a command to the MP, and an output signal processing circuit configured to receive the command from the MP. One of the MP, the main storage circuit, the supplementary storage circuit, the input signal processing circuit, and the output signal processing circuit may include a capacitor structure, which includes a lower electrode, a rutile state lower vanadium dioxide layer on the lower electrode, a rutile state titanium oxide layer on the lower vanadium dioxide layer, and an upper electrode on the titanium oxide layer.

According to other example embodiments, an electronic system may include a control unit, an input unit, an output unit, a storage unit, and a communication unit. One of the control unit, the input unit, the output unit, the storage unit, and the communication unit includes a semiconductor device, which includes a capacitor structure having a lower electrode, a rutile state titanium oxide layer on the lower electrode, a rutile state upper vanadium dioxide layer on the titanium oxide layer, and an upper electrode on the upper vanadium dioxide layer.

Particulars of other embodiments are included in the detailed description and drawings.

### BRIEF DESCRIPTION OF THE DRAWINGS

Example embodiments are described in further detail below with reference to the accompanying drawings. It should be understood that various aspects of the drawings may have been exaggerated for clarity:

FIGS. 1A through 1K are cross-sectional views of structures included in a semiconductor device according to example embodiments;

FIGS. 2A through 2G are flowcharts illustrating a method of forming structures included in a semiconductor device according to example embodiments;

FIGS. 3A through 5E are cross-sectional views illustrating methods of forming structures included in a semiconductor device according to example embodiments;

FIGS. 6A and 6B are schematic diagrams of semiconductor devices including a vanadium dioxide (VO₂) layer and a titanium oxide (TiO₂) layer according to example embodiments;

FIG. 7A is a schematic diagram of a semiconductor module including a semiconductor device having a vanadium dioxide layer and a titanium oxide layer according to example embodiments;

FIG. 7B is a schematic block diagram of an electronic circuit board including a vanadium dioxide layer and a titanium oxide layer according to example embodiments;

FIG. 7C is a schematic block diagram of an electronic system including a semiconductor device or semiconductor module having a vanadium dioxide layer and a titanium oxide layer according to example embodiments;

FIG. 8 is a graph of measurement results showing formation of a titanium oxide layer in a rutile state;

FIG. 9 is a graph of results of X-ray diffraction (XRD) analysis of a titanium oxide layer formed in a rutile state according to example embodiments;

FIG. 10A is a transmission electron microscope (TEM) image of a titanium oxide layer formed in a rutile state according to example embodiments; and

FIG. 10B is an image of results of XRD analysis of a titanium oxide layer formed in a rutile state.

### DETAILED DESCRIPTION OF THE EMBODIMENTS

Various example embodiments will now be described more fully with reference to the accompanying drawings in which some example embodiments are shown. This inventive concept may, however, be embodied in different forms and should not be construed as limited to the embodiments set forth herein. Rather, these embodiments are provided so that this disclosure is thorough and complete and fully conveys the scope of the inventive concept to one skilled in the art. In the drawings, the thicknesses of layers and regions may be exaggerated for clarity. Like numbers refer to like elements throughout.

Embodiments of the present inventive concept are described herein with reference to plan and cross-section illustrations that are schematic illustrations of idealized embodiments of the present inventive concept. As such, variations from the shapes of the illustrations as a result, for example, of manufacturing techniques and/or tolerances, are to be expected. Thus, embodiments of the present inventive concept should not be construed as limited to the particular shapes of regions illustrated herein but are to include deviations in shapes that result, for example, from manufacturing. Thus, the regions illustrated in the figures are schematic in nature and their shapes are not intended to illustrate the precise shape of a region of a device and are not intended to limit the scope of the present inventive concept.

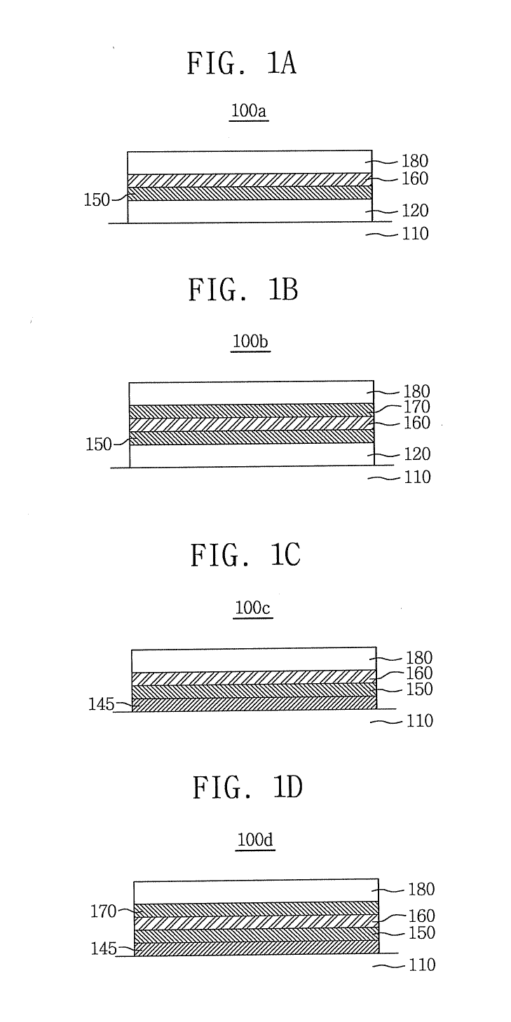

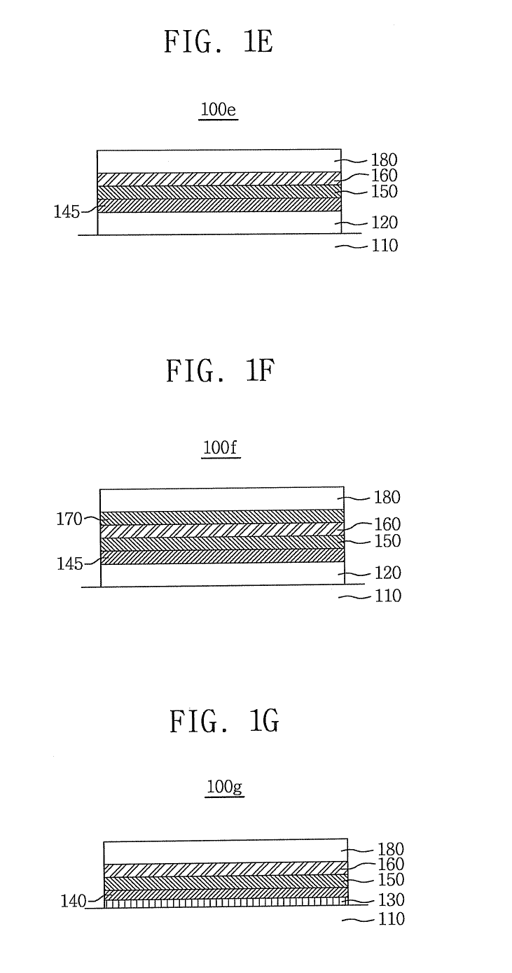

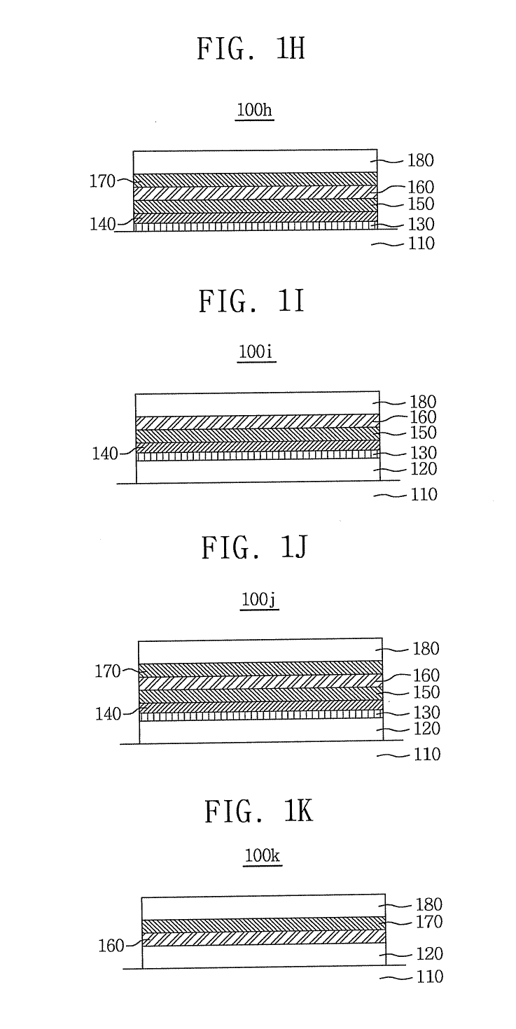

FIGS. 1A through 1I are cross-sectional views of structures included in a semiconductor device according to example embodiments. Referring to FIG. 1A, a structure 100a included in a semiconductor device according to example embodiments may include a lower electrode 120 disposed on a lower layer 110, a rutile state lower vanadium dioxide layer 150 disposed on the lower electrode 120, a rutile state titanium oxide layer 160 disposed on the rutile state lower vanadium dioxide layer 150, and an upper electrode 180 disposed on the rutile state titanium oxide layer 160.

Referring to FIG. 1B, a structure 100b included in a semiconductor device according to other example embodiments may include a lower electrode 120 disposed on a lower layer 110, a rutile state lower vanadium dioxide layer 150 disposed on the lower electrode 120, a rutile state titanium oxide layer 160 disposed on the rutile state lower vanadium dioxide layer 150, a rutile state upper vanadium dioxide layer 170 disposed on the rutile state titanium oxide layer 160, and an upper electrode 180 disposed on the rutile state upper vanadium dioxide layer 170.

Referring to FIG. 1C, a structure 100c included in a semiconductor device according to other example embodiments may include a vanadium (V)-containing material layer 145 disposed on a lower layer 110, a rutile state lower vanadium dioxide layer 150 disposed on the V-containing material layer 145, a rutile state titanium oxide layer 160 disposed on the rutile state lower vanadium dioxide layer 150, and an upper electrode 180 disposed on the titanium oxide layer 160. The V-containing material layer 145 may be a vanadium layer or a vanadium nitride (VN) layer. The V-containing material layer 145 may be used as a lower electrode (refer to 120 in FIG. 1A or 1B).

Referring to FIG. 1D, a structure 100d included in a semiconductor device according to other example embodiments may include a V-containing material layer 145 disposed on a lower layer 110, a rutile state lower vanadium dioxide layer 150 disposed on the V-containing material layer 145, a rutile state titanium oxide layer 160 disposed on the rutile state lower vanadium dioxide layer 150, a rutile state upper vanadium dioxide layer 170 disposed on the rutile state titanium oxide layer 160, and an upper electrode 180 disposed on the rutile state upper vanadium dioxide layer 170. The V-containing material layer 145 may be a vanadium layer or a vanadium nitride layer. The V-containing material layer 145 may be used as a lower electrode (refer to 120 in FIG. 1A or 1B).

Referring to FIG. 1E, a structure 100e included in a semiconductor device according to other example embodiments may include a lower electrode 120 disposed on a lower layer 110, a V-containing material layer 145 disposed on the lower electrode 120, a rutile state lower vanadium dioxide layer 150 disposed on the V-containing material layer 145, a rutile state titanium oxide layer 160 disposed on the rutile state lower vanadium dioxide layer 150, and an upper electrode 180 disposed on the rutile state titanium oxide layer 160. The V-containing material layer 145 may be a vanadium layer or a vanadium nitride layer.

Referring to FIG. 1F, a structure 100f included in a semiconductor device according to other example embodiments may include a lower electrode 120 disposed on a lower layer 110, a V-containing material layer 145 disposed on the lower electrode 120, a rutile state lower vanadium dioxide layer 150 disposed on the V-containing material layer 145, a rutile state titanium oxide layer 160 disposed on the rutile state lower vanadium dioxide layer 150, a rutile state upper vanadium dioxide layer 170 disposed on the rutile state titanium oxide layer 160, and an upper electrode 180 disposed on the rutile state upper vanadium dioxide layer 170. The V-containing material layer 145 may be a vanadium layer or a vanadium nitride layer.

Referring to FIG. 1G, a structure 100g included in a semiconductor device according to other example embodiments may include a vanadium layer 130 disposed on a lower layer 110, a vanadium nitride layer 140 disposed on the vanadium layer 130, a rutile state lower vanadium dioxide layer 150 disposed on the vanadium nitride layer 140, a rutile state titanium oxide layer 160 disposed on the rutile state lower vanadium dioxide layer 150, and an upper electrode 180 disposed on the rutile state titanium oxide layer 160.

Referring to FIG. 1H, a structure 100h included in a semiconductor device according to other example embodiments may include a vanadium layer 130 disposed on a lower layer 110, a vanadium nitride layer 140 disposed on the vanadium layer 130, a rutile state lower vanadium dioxide layer 150 disposed on the vanadium nitride layer 140, a rutile state titanium oxide layer 160 disposed on the rutile state lower vanadium dioxide layer 150, a rutile state upper vanadium dioxide layer 170 disposed on the rutile state titanium oxide layer 160, and an upper electrode 180 disposed on the rutile state upper vanadium dioxide layer 170.

Referring to FIG. 1I, a structure 100i included in a semiconductor device according to other example embodiments may include a lower electrode 120 disposed on a lower layer 110, a vanadium layer 130 disposed on the lower electrode 120, a vanadium nitride layer 140 disposed on the vanadium layer 130, a rutile state lower vanadium dioxide layer 150 disposed on the vanadium nitride layer 140, a rutile state titanium oxide layer 160 disposed on the rutile state lower vanadium dioxide layer 150, and an upper electrode 180 disposed on the rutile state titanium oxide layer 160.

Referring to FIG. 1J, a structure 100j included in a semiconductor device according to other example embodiments may include a lower electrode 120 disposed on a lower layer 110, a vanadium layer 130 disposed on the lower electrode 120, a vanadium nitride layer 140 disposed on the vanadium layer 130, a rutile state lower vanadium dioxide layer 150 disposed on the vanadium nitride layer 140, a rutile state titanium oxide layer 160 disposed on the rutile state lower vanadium dioxide layer 150, a rutile state upper vanadium dioxide layer 170 disposed on the rutile state titanium oxide layer 160, and an upper electrode 180 disposed on the rutile state upper vanadium dioxide layer 170.

Referring to FIG. 1K, a structure 100k included in a semiconductor device according to other example embodiments may include a lower electrode 120 disposed on a lower layer 110, a rutile state titanium oxide layer 160 disposed on the lower electrode 120, a rutile state upper vanadium dioxide layer 170 disposed on the rutile state titanium oxide layer 160, and an upper electrode 180 disposed on the rutile state upper vanadium dioxide layer 170.

The titanium oxide layer 160 may be a titanium dioxide layer. Each of the lower electrode 120 and the upper electrode 180 may be formed of a metal, a metal silicide, a metal alloy, or a metal compound. For example, each of the lower electrode 120 and the upper electrode 180 may be formed of a conductive material, such as copper (Cu), tungsten (W), cobalt (Co), nickel (Ni), tungsten silicide, cobalt silicide, nickel silicide, titanium silicide, tungsten nitride, titanium (Ti) nitride, or other refractory metals. In the present specification, it is assumed that each of the lower electrode 120 and the upper electrode 180 is formed of titanium nitride. This assumption is provided to simplify the kinds of metals used and not intended to limit the scope of the present inventive concept.

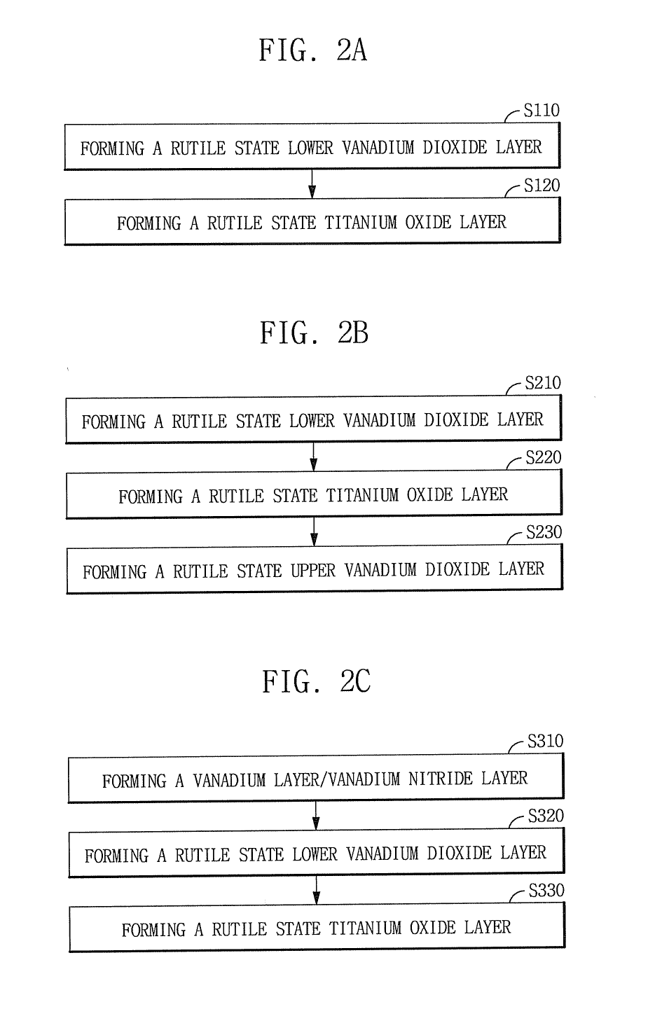

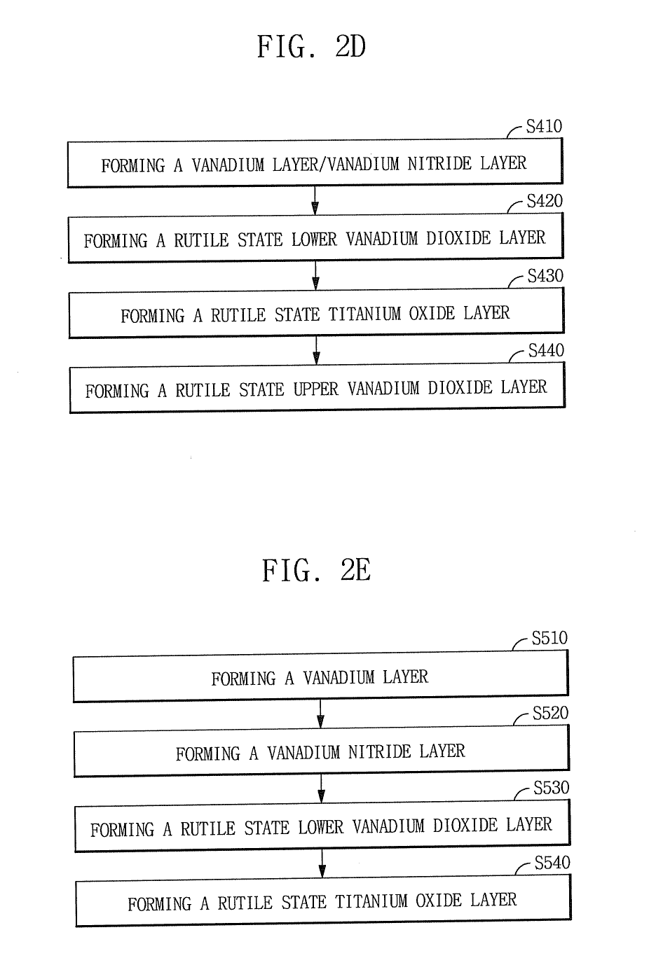

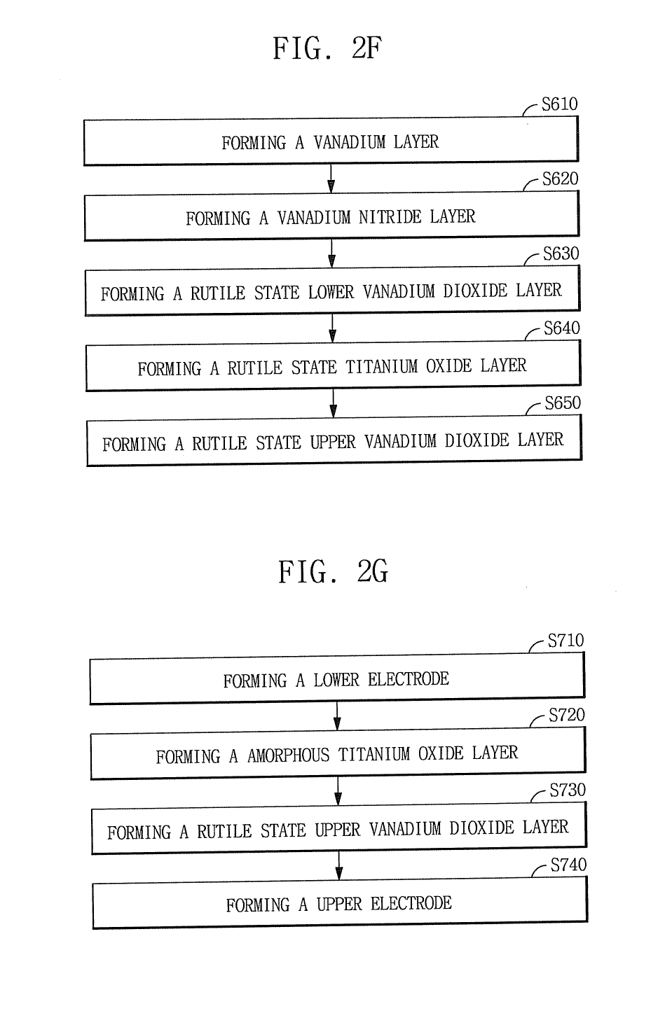

FIGS. 2A through 2G are flowcharts illustrating methods of forming structures included in semiconductor devices according to example embodiments.

Referring to FIG. 2A, a method of foil ring structures included in a semiconductor device according to example embodiments may include forming a rutile state lower vanadium dioxide layer (S110) and forming a rutile state titanium oxide layer (S120).

Referring to FIG. 2B, a method of forming structures included in a semiconductor device according to other example embodiments may include forming a rutile state lower vanadium dioxide layer (S210), forming a rutile state titanium oxide layer (S220), and forming a rutile state upper vanadium dioxide layer (S230).

Referring to FIG. 2C, a method of forming structures included in a semiconductor device according to other example embodiments may include forming a vanadium layer or a vanadium nitride layer (S310), forming a rutile state lower vanadium dioxide layer (S320), and forming a rutile state titanium oxide layer (S330).

Referring to FIG. 2D, a method of forming structures included in a semiconductor device according to other example embodiments may include forming a vanadium layer or vanadium nitride layer (S410), forming a rutile state lower vanadium dioxide layer (S420), forming a rutile state titanium oxide layer (S430), and forming a rutile state upper vanadium dioxide layer (S440).

Referring to FIG. 2E, a method of forming structures included in a semiconductor device according to other example embodiments may include forming a vanadium layer (S510), forming a vanadium nitride layer (S520), forming a rutile state lower vanadium dioxide layer (S530), and forming a rutile state titanium oxide layer (S540).

Referring to FIG. 2F, a method of forming structures included in a semiconductor device according to other example embodiments may include forming a vanadium layer (S610), forming a vanadium nitride layer (S620), forming a rutile state lower vanadium dioxide layer (S630), forming a rutile state titanium oxide layer (S640), and forming a rutile state upper vanadium dioxide layer (S650).

Each of the methods of forming capacitor structures included in the semiconductor device according to the example embodiments, which are described with reference to FIGS. 2A through 2F, may include forming a lower electrode and forming an upper electrode. Referring to FIG. 2G, a method of forming capacitor structures included in a semiconductor device according to other example embodiments may include forming a lower electrode (S710), forming an amorphous titanium oxide layer (S720), forming a rutile state upper vanadium dioxide layer (S730), and forming an upper electrode (S740). The methods proposed according to FIGS. 2A through 2G will now be described in more detail.

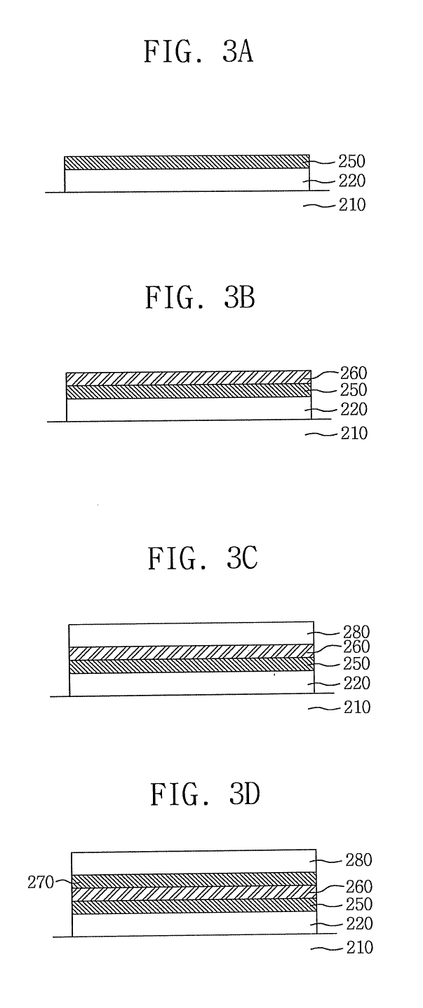

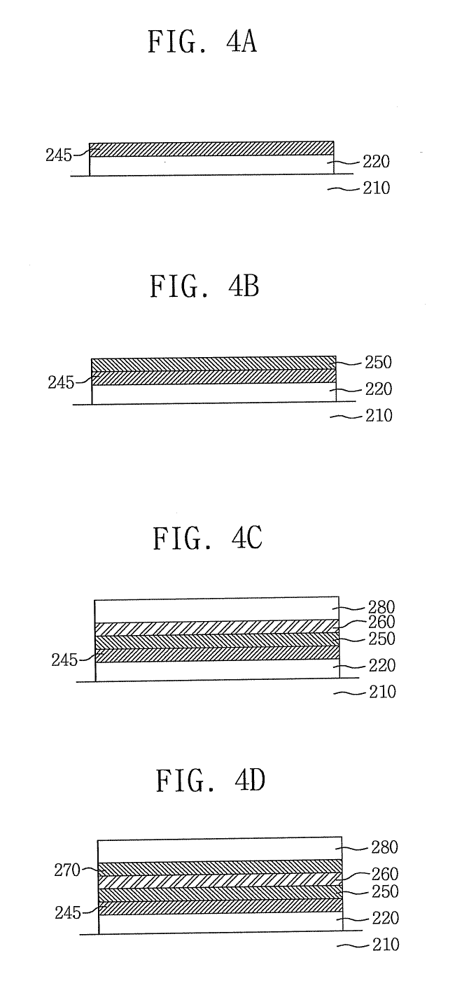

FIGS. 3A through 3D are cross-sectional views illustrating methods of forming structures included in a semiconductor device according to example embodiments. Referring to FIG. 3A, a lower electrode 220 may be formed on a lower layer 210, and a rutile state lower vanadium dioxide layer 250 may be formed on the lower electrode 220. The rutile state lower vanadium dioxide layer 250 may be formed using a physical vapor deposition (PVD) process, a chemical vapor deposition (CVD) process, or an atomic layer deposition (ALD) process. For example, the rutile state lower vanadium dioxide layer 250 may be formed on the lower electrode 220 using a CVD process by which a vanadium (V) precursor and an oxidizer are simultaneously injected into a reaction chamber. Alternatively, the formation of the rutile state lower vanadium dioxide layer 250 may include forming a V-containing material layer and oxidizing the surface of the V-containing material layer. The formation of the rutile state lower vanadium dioxide layer 250 using an ALD process may include supplying a V precursor to a semiconductor substrate where the rutile state vanadium dioxide layer 250 will be formed, for a predetermined time to form a unit chemically attached layer on the surface of the semiconductor substrate, removing a V-rich precursor, which is physically attached on the surface of the semiconductor substrate, using a purge gas, supplying a reactive gas containing an oxidizer to the unit chemically attached layer to form a rutile state unit vanadium dioxide layer, and removing the remaining oxidizer and byproducts using a purge gas. The oxidizer may be ozone (O₃), water vapor (H₂O), oxygen (O₂), nitrous oxide (N₂O), or O₂ plasma. The O₂ plasma may be selected when the ALD process is a plasma ALD process using plasma energy. The purgₑ gas may be aₙ inert gas, such as argon (Aᵣ) gas. The pro_{c}ess of forming the rutile state lower vanadium dioxide layer 250 may be related with a subsequent process of forming a rutile state titanium oxide layer and sensitive particularly to temperature conditions. According to the inventive concept, the process of forming the rutile state lower vanadium dioxide layer may be performed at a temperature of about 500° C. or lower, which may be very important to a technique of forming a rutile state titanium oxide layer as will be described in further detail in connection with a process of forming a rutile state titanium oxide layer. The lower layer 210 may be a semiconductor substrate, a lower interlayer insulating layer, a lower capping layer, a lower conductive interconnection, or a lower via plug.

Referring to FIG. 3B, a rutile state titanium oxide layer 260 may be formed on the rutile state lower vanadium dioxide layer 250. The rutile state titanium oxide layer 260 may be formed using a PVD process, a CVD process, or an ALD process. For example, the rutile state titanium oxide layer 260 may be formed using a CVD process by which a titanium (Ti) precursor and an oxidizer are simultaneously injected into a reaction chamber. The formation of the rutile state titanium oxide layer 260 using an ALD process may include supplying a Ti precursor to a substrate for a predetermined time to form a unit chemically attached layer on the substrate, removing a Ti-rich precursor, which is physically attached on the substrate, using a purge gas, supplying a reactive gas containing an oxidizer to the unit chemically attached layer to form a rutile state unit titanium oxide layer, and removing the remaining reactive gas containing the oxidizer and byproducts using a purge gas. The Ti precursor may be a halide compound, such as Ti-chloride (TiCl₄), and an organic metal compound. The oxidizer contained in the reactive gas may be ozone, water vapor, oxygen, or nitrous oxide. An inert gas, such as Ar gas, may be used as the purge gas. During the formation of the rutile state titanium oxide layer 260 on the rutile state lower vanadium dioxide layer 250, the titanium oxide layer 260 may be formed in a rutile state even at a low temperature. In general, titanium oxide may be easily formed in an anatase state, and an anatase titanium oxide layer must be annealed at a high temperature of about 800° C. or higher in order to state-change the anatase titanium oxide layer into a rutile state titanium oxide layer. Performing a process of forming a rutile state titanium oxide layer or state-changing an anatase titanium oxide layer into a rutile state titanium oxide layer at a temperature of about 800° C. or higher may be difficult because the process may greatly increase the thermal burden of the lower electrode 220. However, according to the present inventive concept, the rutile state lower vanadium dioxide layer 250 may be formed so that the titanium oxide layer 260 may be formed in a rutile state on the rutile state lower vanadium dioxide layer 250 even at a temperature of about 600° C. or lower. As the result of an experiment according to the inventive concept, it was possible to form the rutile state titanium oxide layer 260 at a relatively low temperature of about 500° C. or lower. By optimizing the present inventive concept, a rutile state titanium oxide layer may be formed even at a lower temperature. As a result, a process temperature may be reduced so that process stability can be increased and the thermal burden of other material layers, such as the lower electrode 220, can be reduced, thereby improving the characteristics and productivity of semiconductor devices.

Referring to FIG. 3C, an upper electrode 280 may be formed on the rutile state titanium oxide layer 260. The upper electrode 280 may be formed of a metal, a metal compound, or a metal alloy. Since the upper electrode 280 may be formed of a wide variety of metals, a detailed description thereof will be omitted. In the present embodiment, it is assumed that the upper electrode 280 is formed of titanium nitride. Here, a process of forming a titanium nitride electrode is known, and thus a detailed description will be omitted.

Referring to FIG. 3D, before forming the upper electrode 280, a rutile state upper vanadium dioxide layer 270 may be formed on the titanium oxide layer 260. The rutile state upper vanadium dioxide layer 270 may be formed using the above-described process of forming the rutile state lower vanadium dioxide layer 250. In this case, an upper portion of the titanium oxide layer 260 may be in a less rutile state. For example, the upper portion of the titanium oxide layer 260 may be wholly or partially amorphous. In this case, the rutile state upper vanadium dioxide layer 270 may lead the upper portion of the titanium oxide layer 260 to be state-changed into a rutile state. For example, the upper portion of the titanium oxide layer 260 may be affected by a process of forming the upper vanadium dioxide layer 270 in a rutile state. In general, deposited titanium oxide may be in an amorphous or anatase state due to differences in crystallinity and crystallization stability caused by deposition conditions or deposited thicknesses. For example, when processing conditions (e.g., a relatively high process temperature and a sufficient process time) under which titanium oxide may be stably crystallized are satisfied, the titanium oxide may be in a crystalline state, that is, an anatase state. However, when titanium oxide is formed under changed deposition conditions, for example, at a relatively low process temperature for a short amount of time, the deposited titanium oxide may be in an amorphous state. By forming a rutile state vanadium dioxide layer on an amorphous titanium oxide layer, a state-change process may be induced to crystallize the titanium oxide in a rutile state.

In addition, the formation of the rutile state lower vanadium dioxide layer 250 may be omitted. The amorphous titanium oxide layer 260 may be formed on the lower electrode 220, and the rutile state upper vanadium dioxide layer 270 may be formed on the amorphous titanium oxide layer 260 so that the amorphous titanium oxide layer 260 can be state-changed into a rutile state titanium oxide layer. The titanium oxide layer 260 may be a titanium dioxide layer.

FIGS. 4A through 4D are cross-sectional views illustrating methods of forming structures included in a semiconductor device according to example embodiments.

Referring to FIG. 4A, a lower electrode 220 may be formed on a lower layer 210, and a V-containing material layer 245 may be formed on the lower electrode 220. A method of forming the V-containing material layer 245 may be understood with reference to FIG. 3 and the description thereof.

Referring to FIG. 4B, a rutile state lower vanadium dioxide layer 250 may be formed on the V-containing material layer 245. The formation of the rutile state lower vanadium dioxide layer 250 may include oxidizing the top surface of the V-containing material layer 245. When the V-containing material layer 245 is wholly oxidized, only the rutile state lower vanadium dioxide layer 250 may be remained as shown in FIG. 3A, while when an upper portion of the V-containing material layer 245 is partially oxidized, the V-containing material layer 245 and the rutile state lower vanadium dioxide layer 250 may be obtained.

Referring to FIG. 4C, a rutile state titanium oxide layer 260 may be formed on the rutile state lower vanadium dioxide layer 250. Also, an upper electrode 280 may be formed on the rutile state titanium oxide layer 260. These processes may be understood with reference to FIGS. 3B and 3C and descriptions thereof.

Referring to FIG. 4D, before forming the upper electrode 280, a rutile state upper vanadium dioxide layer 270 may be formed on the titanium oxide layer 260. The process may be understood with reference to FIG. 3D and the description thereof.

In FIGS. 4A through 4D, the V-containing material layer 245 may be formed of vanadium or vanadium nitride. The formation of the vanadium nitride layer 240 may include forming the V-containing material layer 245 and nitrifying the surface of the V-containing material layer 245. Alternatively, the formation of the vanadium nitride layer 240 may include causing a reaction between a V precursor and a nitration agent. A process of forming the vanadium nitride layer 240 may be selected in consideration of various parameters, such as the kind and performance of a deposition apparatus, the thickness of a desired layer, and the reactivity and temperature properties of other related layers. In the present embodiment, the lower electrode 220 may be omitted. The titanium oxide layer 260 may be a titanium dioxide (TiO₂) layer.

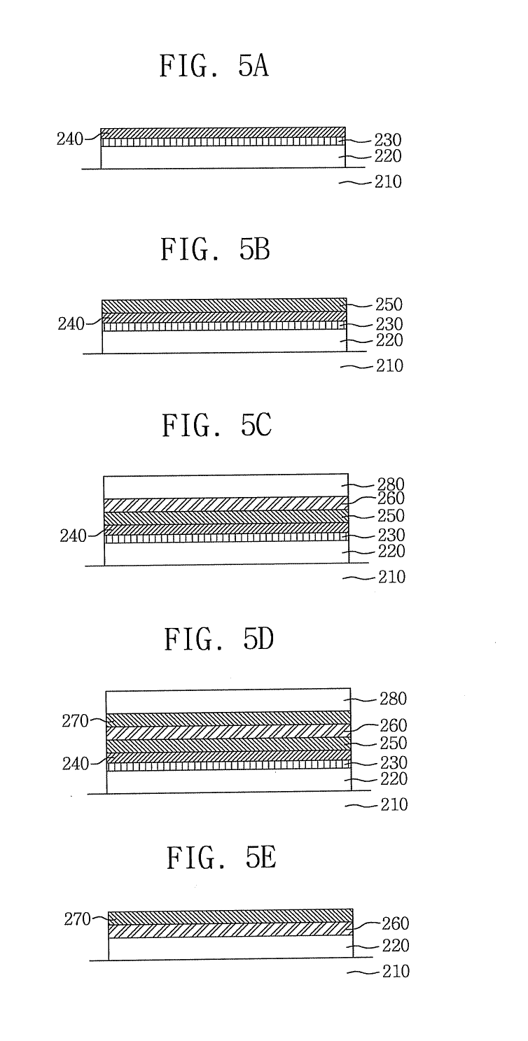

FIGS. 5A through 5D are cross-sectional views illustrating methods of forming capacitor structures included in a semiconductor device according to example embodiments.

Referring to FIG. 5A, a lower electrode 220 may be formed on a lower layer 210, a vanadium layer 230 may be formed on the lower electrode 220, and a vanadium nitride layer 240 may be formed on the vanadium layer 230. The vanadium layer 230 may be formed using a PVD process, a CVD process, or an ALD process. For instance, the formation of the vanadium layer 230 using a PVD process may include sputtering a V target using a nitride gas or sputtering a vanadium nitride target using an inert gas. The formation of the vanadium layer 230 using a CVD process may include simultaneously supplying a V precursor and a reducing agent to a reaction chamber to form a vanadium metal or simultaneously supplying the V precursor and a nitration agent into the reaction chamber. The formation of the vanadium layer 230 using an ALD process may include supplying a V precursor to a semiconductor substrate for a predetermined time to form a unit chemically attached layer, removing a physically attached V precursor using a purge gas, supplying a reducing agent to reduce the unit chemically attached layer to a vanadium metal layer, and removing the remaining reducing agent and byproducts using a purge gas. The formation of the vanadium nitride layer 240 may include nitrifying the surface of the vanadium layer 230 or forming an additional vanadium nitride layer 240 directly on the vanadium layer 230. As mentioned above with reference to FIG. 4D, since a process of forming the vanadium nitride layer 240 may be selected in consideration of various process parameters, it cannot be said that one process is better. In general, the process forming the vanadium nitride layer 240 may be selected in consideration of a known relationship between titanium and titanium nitride. However, in order to obtain a purer layer quality, the vanadium nitride layer 240 may be fanned without forming the vanadium layer 230. The purity of layer quality of the vanadium nitride layer 240 may be estimated based on the uniformity of distribution of stable coupling of vanadium with nitrogen in a material.

Referring to FIG. 5B, a rutile state lower vanadium dioxide layer 250 may be formed on the vanadium nitride layer 240. The formation of the rutile state lower vanadium dioxide layer 250 may include oxidizing the surface of the vanadium nitride layer 240 or forming a rutile state vanadium dioxide layer directly on the vanadium nitride layer 240. The formation of the rutile state lower vanadium dioxide layer 250 directly on the vanadium nitride layer 240 may be performed using a PVD process, a CVD process, or an ALD process.

Referring to FIG. 5C, a rutile state titanium oxide layer 260 may be formed on the rutile state lower vanadium dioxide layer 250. Also, an upper electrode 280 may be formed on the rutile state titanium oxide layer 260.

Referring to FIG. 5D, before forming the upper electrode 280, a rutile state upper vanadium dioxide layer 270 may be formed on the titanium oxide layer 260. In this case, an upper portion of the titanium oxide layer 260 may be in a less rutile state. For example, the upper portion of the titanium oxide layer 260 may be wholly or partially amorphous.

Referring now only to FIG. 5E, a lower electrode 220 may be formed on a lower layer 210, an amorphous titanium oxide layer 260 may be formed on the lower electrode 220, and a rutile state upper vanadium dioxide layer 270 may be formed on the titanium oxide layer 260. In this case, the titanium oxide layer 260 may make the transition from a wholly or partially amorphous state to a rutile state.

Although a technique of forming the rutile state titanium oxide layer 260 using ruthenium (Ru) or iridium (Ir) has conventionally been proposed, Ru or Ir may be susceptible to being excessively oxidized and changed in composition during an oxidation process and being volatilized to degrade process stability. Since rutile state vanadium dioxide according to the inventive concept has about the same lattice constant as titanium oxide, the rutile state vanadium dioxide may enable easier and more stable formation of rutile state titanium oxide.

In FIGS. 5A through 5E, the lower vanadium dioxide layer 250, the titanium oxide layer 260, and the upper vanadium dioxide layer 270 may constitute a single dielectric layer. The titanium oxide layer 260 may be a titanium dioxide layer.

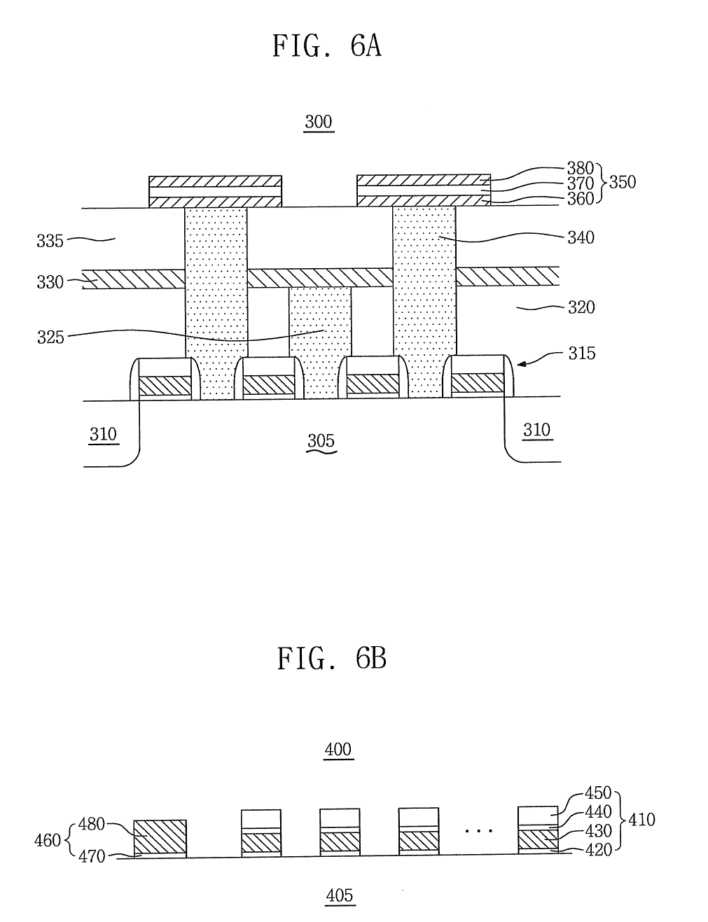

FIGS. 6A and 6B are schematic diagrams of semiconductor devices including a rutile state vanadium dioxide layer and a rutile state titanium oxide layer according to example embodiments. FIG. 6A illustrates an example of a dynamic random access memory (DRAM) semiconductor device, while FIG. 6B illustrates an example of a flash memory device. Referring to FIG. 6A, a semiconductor device 300 according to example embodiments may include a semiconductor substrate 305, isolation regions 310, gates 315, a first interlayer insulating layer 320, a bit line contact 325, a bit line 330, a second interlayer insulating layer 335, a storage contact 340, and a storage 350. The storage 350 may include a lower electrode 360, a storage dielectric layer 370, and an upper electrode 380. The storage dielectric layer 370 may include a rutile state vanadium dioxide layer and a rutile state titanium oxide layer. The structures and functions of components that are not described in detail may be fully understood by one skilled in the art. In addition, in consideration of only the shape of the storage 350, the semiconductor device 300 of FIG. 6A may be interpreted as a logic semiconductor device including a metal-insulator-metal (MIM) capacitor, a static RAM (SRAM), a flash memory device, a resistive RAM (RRAM), a state-changeable RAM (PRAM), a magnetic RAM (MRAM), or other semiconductor devices.

Referring to FIG. 6B, a semiconductor device 400 according to other example embodiments may include a plurality of gates 410 disposed on a semiconductor substrate 405. Each of the gates 410 may include a gate insulating layer 420, a lower gate electrode 430, an inter-gate dielectric layer 440, and an upper gate electrode 450. The inter-gate dielectric layer 440 may include a rutile state vanadium dioxide layer and a rutile state titanium oxide layer. The lower and upper gate electrodes 430 and 450 may be respectively interpreted as being similar to the lower electrode 120 or 220 and the upper electrode 180 or 280 described in the present specification. The lower gate electrode 430 may be a floating gate electrode, and the upper gate electrode 450 may be a control gate electrode. Alternatively, in the case of a charge-trap-flash (CTF) memory device, each of the gates 410 may further include a charge-trap gate structure 460 illustrated in a left portion of FIG. 6B. The charge-trap gate structure 460 may include a charge-trap dielectric layer 470 and a gate electrode 480. The charge-trap dielectric layer 470 may include a rutile state vanadium dioxide layer and a rutile state titanium oxide layer. The structures and functions of components that are not described in detail may be fully understood by one skilled in the art.

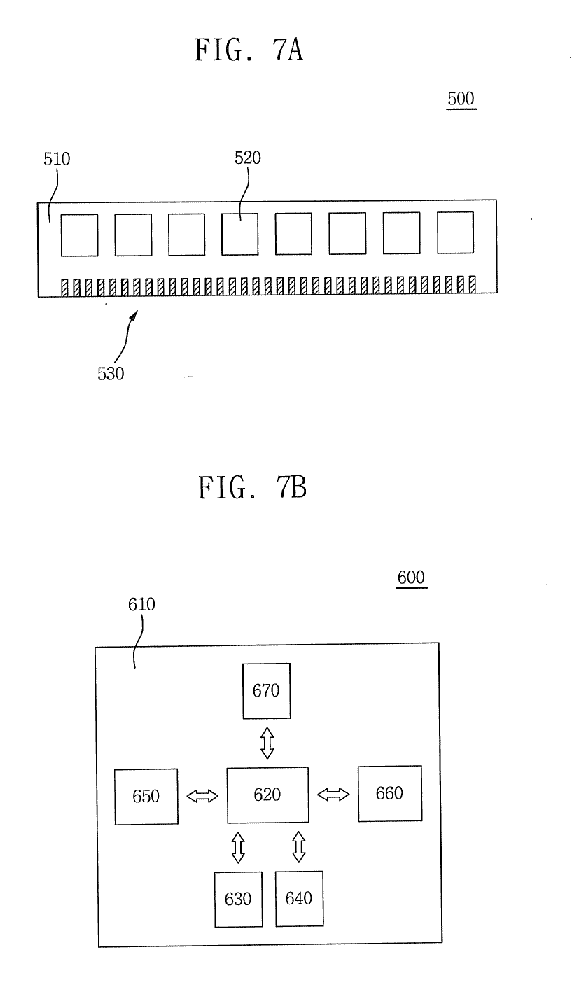

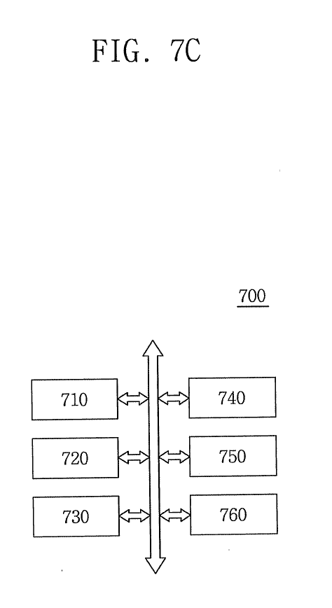

FIG. 7A is a schematic diagram of a semiconductor module including a semiconductor device having a capacitor with a rutile state vanadium dioxide layer and a rutile state titanium oxide layer according to example embodiments.

Referring to FIG. 7A, a semiconductor module 500 according to example embodiments may include a module substrate 510, a plurality of semiconductor devices 520 disposed on the module substrate 510, and module contact terminals 530 disposed in a row on an edge of the module substrate 510 and electrically connected to the semiconductor devices 520, respectively. The module substrate 510 may be a printed circuit board (PCB). Both surfaces of the module substrate 510 may be used. In other words, the semiconductor devices 520 may be disposed on both front and rear surfaces of the module substrate 510. Although FIG. 7A illustrates 8 semiconductor devices 520 arranged on the front surface of the module substrate 510, the inventive concept is not limited thereto. Also, the semiconductor module 500 may further include an additional semiconductor device configured to control the semiconductor devices 520 or semiconductor packages. Thus, the shape of the single semiconductor module 500 is not limited to the number of the semiconductor devices 520 shown in FIG. 7A. At least one of the semiconductor devices 520 may include a capacitor including a rutile state vanadium dioxide layer and a rutile state titanium oxide layer according to example embodiments. The module contact terminals 530 may be variously set according to the standard of the semiconductor module 500. Thus, the number of the module contact terminals 530 shown in FIG. 7A may be insignificant.

FIG. 7B is a schematic block diagram of an electronic circuit board including a semiconductor device having a capacitor with a rutile state vanadium dioxide layer and a rutile state titanium oxide layer according to example embodiments.

Referring to FIG. 7B, an electronic circuit board 600 according to example embodiments may include a microprocessor (MP) 620 disposed on a circuit board 610, a main storage circuit 630 and a supplementary storage circuit 640 configured to communicate with the MP 620, an input signal processing circuit 650 configured to transmit a command to the MP 620, an output signal processing circuit 660 configured to receive the command from the MP 620, and a communicating signal processing circuit 670 configured to transmit and receive electric signals to and from other circuit boards. Arrows may be interpreted as paths through which electric signals may be transmitted. The MP 620 may receive and process various electric signals and output processing results and control other components of the electronic circuit board 610. The MP 620 may be interpreted as, for example, a central processing unit (CPU) and/or a main control unit (MCU). The main storage circuit 630 may temporarily store data always or frequently required by the MP 620 or pre- and post-processing data. Since the main storage circuit 630 requires high response speed, the main storage circuit 630 may include a semiconductor memory device. More specifically, the main storage circuit 630 may be a cache semiconductor memory or include an SRAM, a DRAM, an RRAM, and applied semiconductor memories thereof, such as a utilized RAM, a ferroelectric RAM (FRAM), a fast-cycle RAM, a PRAM, an MRAM, and other semiconductor memories. In addition, the main storage circuit 630 may include a volatile random access memory device or a nonvolatile random access memory device. In the present embodiment, the main storage circuit 630 may include at least one semiconductor device or semiconductor module 500 including a capacitor having a rutile state vanadium dioxide layer and a rutile state titanium oxide layer according to example embodiments. The supplementary storage circuit 640 may be a mass storage device, which is a nonvolatile semiconductor memory such as a flash memory device, a hard disk drive (HDD) using a magnetic field, or a compact disk drive (CDD) using light. The supplementary storage circuit 640 may be used to store a large amount of data even at low processing speed as compared with the main storage circuit 630. The supplementary storage circuit 640 may include a random access nonvolatile memory device or a non-random access nonvolatile memory. The supplementary storage circuit 640 may include at least one semiconductor device or semiconductor module 500 having a capacitor with a rutile state vanadium dioxide layer and a rutile state titanium oxide layer according to example embodiments. The input signal processing circuit 650 may convert an external command into an electric signal or transmit an external electric signal to the MP 620. The external command or electric signal may be an operation command, an electric signal to be processed, or data to be stored. The input signal processing circuit 650 may be, for example, a terminal signal processing circuit, an image signal processing circuit, one of various sensors, or an input signal interface. The terminal signal processing circuit may be configured to process a signal transmitted from a keyboard, a mouse, a touch pad, an image recognizer, or various sensors, and the image signal processing circuit may be configured to process image signals transmitted from a scanner or a camera. The input signal processing circuit 650 may include at least one semiconductor device or semiconductor module having a capacitor with a rutile state vanadium dioxide layer and a rutile state titanium oxide layer according to example embodiments. The output signal processing circuit 660 may be a component configured to externally transmit the electric signal processed by the MP 620. For example, the output signal processing circuit 660 may be a graphic card, an image processor, an optical converter, a beam panel card, or a multifunctional interface circuit. The output signal processing circuit 660 may include at least one semiconductor device or semiconductor module 500 having a rutile state vanadium dioxide layer and a rutile state titanium oxide layer according to example embodiments. The communicating signal processing circuit 670 may be a component configured to directly transmit or receive electric signals to or from another electronic system or circuit board without passing through the input signal processing circuit 650 or the output signal processing circuit 660. For example, the communicating signal processing circuit 670 may be a modem of a personal computer (PC) system, a local area network (LAN) card, or one of various interface circuits. The communicating signal processing circuit 670 may include at least one semiconductor device or semiconductor module 500 having a capacitor with a rutile state vanadium dioxide layer and a rutile state titanium oxide layer according to example embodiments.

FIG. 7C is a schematic block diagram of an electronic system including a semiconductor device or semiconductor module having a capacitor with a rutile state vanadium dioxide layer and a rutile state titanium oxide layer according to example embodiments.

Referring to FIG. 7C, an electronic system 700 according to example embodiments may include a control unit 710, an input unit 720, an output unit 730, and a storage unit 740. Also, the electronic system 700 may further include a communication unit 750 and/or an operation unit 760. The control unit 710 may control all of the electronic system 700 and respective components at one time. The control unit 710 may be interpreted as a CPU or MCU. The control unit 710 may include the electronic circuit board 600 according to the example embodiments. Also, the control unit 710 may include at least one semiconductor device or semiconductor module 500 including a capacitor having a rutile state vanadium dioxide layer and a rutile state titanium oxide layer according to example embodiments. The input unit 720 may transmit an electric command signal to the control unit 710. The input unit 720 may be an image recognizer, such as a keyboard, a keypad, a mouse, a touch pad, or a scanner, or one of various input sensors. The input unit 720 may include at least one semiconductor device or semiconductor module 500 including a capacitor including a rutile state vanadium dioxide layer and a rutile state titanium oxide layer according to example embodiments. The output unit 730 may receive an electric command signal from the controller 710 and output a processing result of the electronic system 700. The output unit 730 may be a monitor, a printer, a beam irradiator, or one of various mechanical apparatuses. The output unit 730 may include at least one semiconductor device or semiconductor module 500 including a capacitor having a rutile state vanadium dioxide layer and a rutile state titanium oxide layer according to example embodiments. The storage unit 740 may be a component configured to temporarily or permanently store signals to be processed or already processed by the control unit 710. The storage unit 740 may be physically and electrically connected or combined with the control unit 710. The storage unit 740 may be a semiconductor memory device, a magnetic storage device such as a hard disk, an optical storage device such as a compact disk, or a server having another data storage function. Also, the storage unit 740 may include at least one semiconductor device or semiconductor module 500 having a capacitor with a rutile state vanadium dioxide layer and a rutile state titanium oxide layer according to example embodiments. The communication unit 750 may receive an electric command signal from the control unit 710 and transmit or receive the electric signal to or from another electronic system. The communication unit 750 may be a wired transceiving device such as a modem or a LAN card, a wireless transceiving device such as a wireless broadband (WiBro) interface, or an infrared (IR) port. Also, the communication unit 750 may include at least one semiconductor device or semiconductor module 500 having a capacitor with a rutile state vanadium dioxide layer and a rutile state titanium oxide layer according to example embodiments. The operation unit 760 may be capable of physical or mechanical operations in response to commands of the control unit 710. For example, the operation unit 760 may be a component capable of mechanical operations, such as a floater, an indicator, or an up/down operator. The electronic system 700 according to example embodiments may be a computer, a network server, a networking printer, a scanner, a wireless controller, a mobile communication terminal, an exchange, or one of other electronic devices capable of programmed operations.

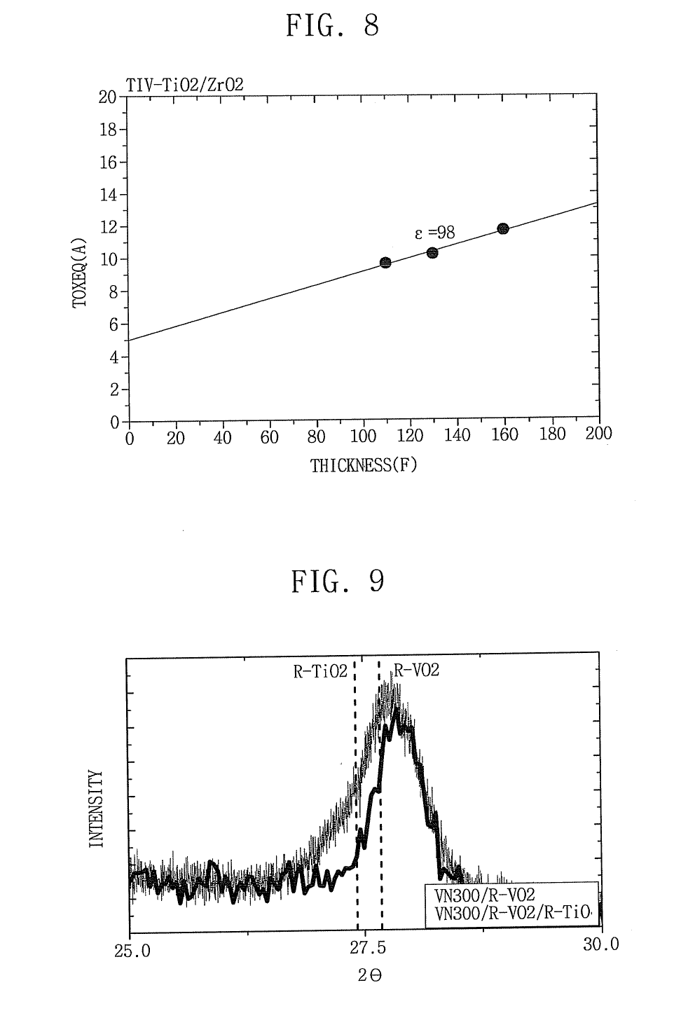

FIG. 8 is a graph of measurement results showing formation of a titanium oxide layer in a rutile state. In FIG. 8, an abscissa denotes the thickness (Å) of a titanium oxide layer, and an ordinate denotes an equivalent oxide thickness (Å). The dielectric constant of a dielectric layer may be calculated using a slope of the graph of FIG. 8.

Referring to FIG. 8, when the titanium oxide layer has a thickness of about 110 Å, the equivalent oxide thickness is about 5 Å, when the titanium oxide layer has a thickness of about 130 Å, the equivalent oxide thickness is about 10 Å, and when the titanium oxide layer has a thickness of about 160 Å, the equivalent oxide thickness is about 12 Å. The equivalent oxide thickness may refer to a thickness into which the thickness of the dielectric layer is converted on the basis of a silicon oxide layer. Since the silicon oxide layer has a dielectric constant of about 3.9, the dielectric constant of the titanium oxide layer may be converted into a dielectric constant of about 98. When the dielectric constant of the titanium oxide layer approximates 100, it can be seen that the titanium oxide layer is formed in a rutile state. In the present experiment, a protection layer was formed on a titanium oxide layer to ensure experimental stability. The protection layer may prevent functional groups or extraneous matters from diffusing into the titanium oxide layer. In the present experiment, a zirconium oxide (ZrO₂) layer was used as the protection layer. Therefore, the measurement result shown in FIG. 8 may be the sum of thicknesses of the titanium oxide layer and the zirconium oxide layer.

FIG. 9 is a graph of results of X-ray diffraction (XRD) analysis of a titanium oxide layer formed in a rutile state according to example embodiments. In FIG. 9, an abscissa denotes a diffraction angle of 2 θ, and an ordinate denotes the intensity of diffracted X rays. Also, a thick line shows a result of XRD analysis of a vanadium nitride layer and a rutile state vanadium dioxide layer as deposited, while a thin line shows a result of XRD analysis of the resultant structure in which a titanium oxide layer is formed on the vanadium nitride layer and the rutile state vanadium dioxide layer. Referring to FIG. 9, it can be seen that the thin line had far higher X-ray intensity than the thick line around a diffraction angle of about 27.5°. Therefore, it can be concluded that the titanium oxide layer obtained at the diffracted angle of about 27.5° was formed in a rutile state.

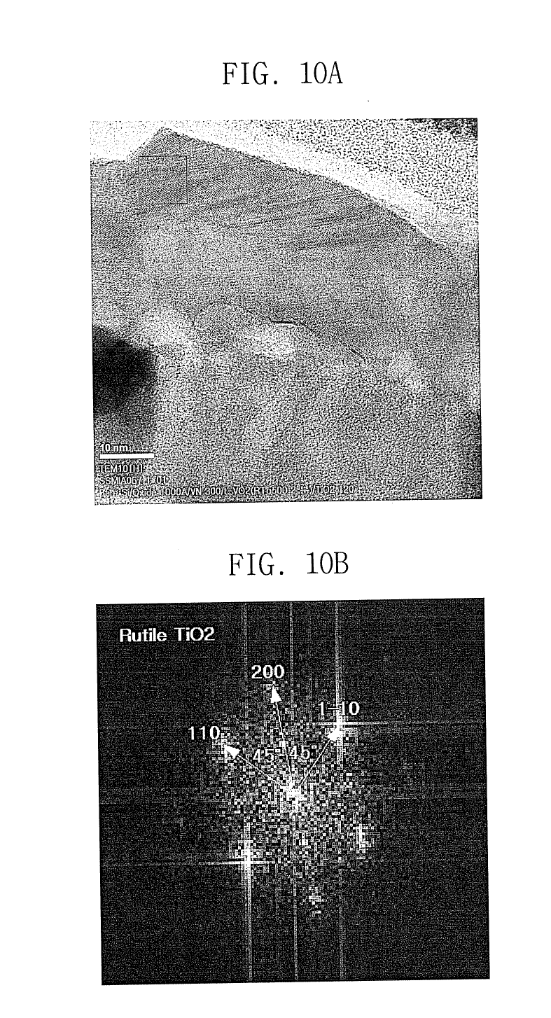

FIG. 10A is a transmission electron microscope (TEM) image of a titanium oxide layer formed in a rutile state according to example embodiments, and FIG. 10B is an image of results of XRD analysis of a titanium oxide layer formed in a rutile state.

Referring to FIGS. 10A and 10B, a titanium oxide layer according to example embodiments may have TEM diffraction pattern directions <110> and <200>. Each material may have intrinsic diffraction pattern directions according to its crystalline state. A titanium oxide layer diffracted in directions <110> and <200> may be described as a rutile titanium oxide layer according to example embodiments.

In addition, the names and functions of unshown components may be easily understood with reference to other drawings of the present specification and descriptions thereof.

According to example embodiments as described above, a semiconductor device including a capacitor having a high dielectric constant can be fabricated at a low temperature so that process stability can be improved, thereby enhancing the characteristics and productivity of semiconductor devices.

While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims.

While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims.

1.-10. (canceled)

11. A method of fabricating a semiconductor device, comprising:
forming a lower electrode;
forming a rutile state lower vanadium dioxide layer on the lower electrode;
forming a rutile state titanium oxide layer on the lower vanadium dioxide layer; and
forming an upper electrode on the titanium oxide layer.

12. The method of claim 11, wherein the lower electrode includes vanadium.

13. The method of claim 12, wherein the lower electrode includes a vanadium layer or a vanadium nitride layer.

14. The method of claim 13, wherein the lower electrode includes:
a vanadium layer; and
a vanadium nitride layer disposed on the vanadium layer.

15. The method of claim 12, wherein forming the lower vanadium dioxide layer includes oxidizing the surface of the lower electrode including vanadium.

16. The method of claim 11, further comprising forming a rutile state upper vanadium dioxide layer between the titanium oxide layer and the upper electrode.

17. The method of claim 11, wherein the lower electrode is formed of a metal compound containing titanium.

18. The method of claim 11, wherein the titanium oxide layer is formed at a temperature of about 500° C. or lower.

19. A method of fabricating a semiconductor device, comprising:
forming a lower electrode;
forming a titanium oxide layer including an amorphous portion on the lower electrode;
forming a rutile state upper vanadium dioxide layer on the titanium oxide layer; and
forming an upper electrode on the upper vanadium dioxide layer.

20. The method of claim 19, wherein the amorphous portion of the titanium oxide layer is state-changed into a rutile state while forming the upper vanadium dioxide layer.
